(19) United States
(12) Patent Application Publication
(10) Pub. No.: US 2026/0334277 A1
(43) Pub. Date: Oct. 22, 2026

(54) SEMICONDUCTOR PACKAGE COMPATIBLE WITH GOLD BACKING AND MOLD COMPOUND

(71) Applicant: Qorvo US, Inc., Greensboro, NC (US)

(72) Inventor: Md Hasnine, Wylie, TX (US)

(21) Appl. No.: 19/571,997

(22) Filed: Mar. 19, 2026

Related U.S. Application Data
(60) Provisional application No. 63/789,693, filed on Apr. 16, 2025.

(51) Int. Cl. H10W 72/30; H10W 72/00; H10W 74/01; H10W 74/10; H10W 74/15; H10W 90/00

(52) U.S. Cl. CPC H10W 72/322; H10W 72/07338; H10W 74/012; H10W 74/121; H10W 74/15; H10W 90/731; H10W 72/352; H10W 72/354; H10W 72/877; H10W 90/724; H10W 90/7295

(57) ABSTRACT

A circuit package includes a die, a gold backing layer adhered to a top side of the die, a conductive post projecting from the bottom side of the die, and a conductive via electrically coupling the conductive post to the gold backing layer. The circuit package also includes a substrate including a conductive pad, a solder bond coupling the conductive post to the conductive pad, a cured underfill layer positioned between the die and the substrate and coupling the die to the substrate, a cured molding compound surrounding the die and coupling the die to the substrate, and at least one interlayer coupling the gold backing layer to the molding compound.

### CROSS REFERENCE TO RELATED APPLICATIONS

This application claims the priority benefit under 35 U.S.C. §119(e) of U.S. Provisional Patent Application No. 63/789,693 filed 16 Apr. 2025, hereby incorporated by reference in its entirety as though fully set forth herein.

### TECHNICAL FIELD

The subject matter described herein relates to devices, systems, and methods for preventing delamination of gold-backed flip chips from mold compound packaging. This gold-to-epoxy compatibility system has particular but not exclusive utility for radio frequency integrated circuits (RF ICs) much as monolithic microwave integrated circuits (MMICs).

### BACKGROUND

Monolithic microwave integrated circuits (MMICs) are used in many RF applications. Some MMICs and other RF ICs are flip chip (FC) designs, where the chip is attached to a substrate with the active side facing down. For RF gallium nitride/gallium arsenide (GaN/GaAs) flip-chip (FC) dies, electrical communication with pads and traces on the substrate is achieved through copper pillars (CuP) and solder caps, with the source connection routed to the backside through a through-semiconductor via (TSV). Gold (Au) is employed as the backside metallization, functioning as the MMIC RF ground plane and connecting the backside via to the ground.

In plastic-encapsulated packages, an epoxy mold compound (EMC) is used to encapsulate the package, providing protection against thermo-mechanical stresses such as coefficient of thermal expansion (CTE) mismatch, as well as other environmental factors, including routine handling, shock and vibration, etc. EMCs are thus selected for their thermo-mechanical properties, and for their adhesion to the substrate material (e.g., a fiber-reinforced material such as FR4) and to the IC die material (e.g., GaN, GaAs, etc.). Additionally, the adhesion strength between the mold compound and the die’s backside is critical to maintaining package integrity and ensuring long-term reliability under challenging operating conditions. However, the adhesion between typical epoxy mold compounds and the Au metallization may be inherently weak, often leading to delamination during stress tests such as moisture sensitivity level 3 (MSL3), highly accelerated stress test (HAST), and temperature cycling. This delamination poses a significant reliability risk, as it can create pathways for moisture ingress, resulting in corrosion and potential electrical failure of the device.

The information included in this Background section of the specification, including any references cited herein and any description or discussion thereof, is included for technical reference purposes only and is not to be regarded as subject matter by which the scope of the disclosure is to be bound.

### SUMMARY

To address the challenges described above, there is a need for solutions that enhance the adhesion between the die’s backside Au metallization and the epoxy mold compound. Such improvements help mitigate delamination risks and enhance the overall reliability of electronic packages in demanding environments. Disclosed is a gold-to-epoxy compatibility system.

One general aspect includes a circuit package. The circuit package includes a die. The package also includes a gold backing layer adhered to a top side of the die. The package also includes a conductive post projecting from a bottom side of the die. The package also includes a conductive via electrically coupling the conductive post to the gold backing layer. The package also includes a substrate may include a conductive pad. The package also includes a solder bond coupling the conductive post to the conductive pad. The package also includes a cured underfill layer positioned between the die and the substrate and coupling the die to the substrate. The package also includes a cured molding compound surrounding the die and coupling the die to the substrate. The package also includes at least one interlayer coupling the gold backing layer to the molding compound.

Implementations may include one or more of the following features. In some embodiments, the at least one interlayer may include a cured adhesive. In some embodiments, the cured adhesive may include an epoxy. In some embodiments, the at least one interlayer may include a sintered material. In some embodiments, the at least one interlayer may include a conductive mesh, block, or foil. In some embodiments, the at least one interlayer has a composition selected to adhere to both the gold backing layer and the cured molding compound. In some embodiments, the circuit package may include a land grid array or ball grid array coupled to a bottom side of the substrate.

One general aspect includes a method for producing a circuit package. The method includes providing a circuit that may include: a die, a gold backing layer adhered to a top side of the die, a conductive post projecting from a bottom side of the die, and a conductive via electrically coupling the conductive post to the gold backing layer. The method also includes providing a substrate that may include a conductive pad. The method also includes, with a solder bond, coupling the conductive post to the conductive pad. The method also includes coupling the die to the substrate by injecting an underfill layer between the die and the substrate. The method also includes curing the underfill layer. The method also includes adding at least one interlayer onto the gold backing layer. The method also includes surrounding the die with a molding compound that couples the die to the substrate. The method also includes curing the molding compound.

Implementations may include one or more of the following features. In some embodiments, the at least one interlayer may include an adhesive, and where the method further may include curing the adhesive. In some embodiments, the adhesive may include an epoxy. In some embodiments, the at least one interlayer may include a sinterable material, and the method further may include sintering the sinterable material. In some embodiments, the at least one interlayer may include a conductive mesh, block, or foil. In some embodiments, the at least one interlayer has a composition selected to adhere to both the gold backing layer and the cured molding compound. In some embodiments, the method may include coupling a land grid array or ball grid array to a bottom side of the substrate.

One general aspect includes a wireless device. The wireless device includes a circuit package, which may include: a die, a gold backing layer adhered to a top side of the die, a conductive post projecting from a bottom side of the die, a conductive via electrically coupling the conductive post to the gold backing layer, a substrate may include a conductive pad, a solder bond coupling the conductive post to the conductive pad, a cured underfill layer positioned between the die and the substrate and coupling the die to the substrate, a cured molding compound surrounding the die and coupling the die to the substrate, and at least one interlayer coupling the gold backing layer to the molding compound.

Implementations may include one or more of the following features. In some embodiments, the at least one interlayer may include a cured adhesive. In some embodiments, the cured adhesive may include an epoxy. In some embodiments, the at least one interlayer may include a sintered material. In some embodiments, the at least one interlayer may include a conductive mesh, block, or foil. In some embodiments, the wireless device may include a land grid array or ball grid array coupled to a bottom side of the substrate.

The gold-to-epoxy compatibility system disclosed herein has particular, but not exclusive, utility for packaging of RF IC flip chip designs.

This Summary is provided to introduce a selection of concepts in a simplified form that are further described below in the Detailed Description. This Summary is not intended to identify key features or essential features of the claimed subject matter, nor is it intended to limit the scope of the claimed subject matter. A more extensive presentation of features, details, utilities, and advantages of the gold-to-epoxy compatibility system, as defined in the claims, is provided in the following written description of various embodiments of the disclosure and illustrated in the accompanying drawings.

### BRIEF DESCRIPTION OF THE DRAWINGS

Illustrative embodiments of the present disclosure will be described with reference to the accompanying drawings, of which:

FIG. 1 is schematic, diagrammatic, side cross-sectional view of an existing flip-chip integrated circuit, in accordance with at least one embodiment of the present disclosure.

FIG. 2 is a schematic, diagrammatic, side cross-sectional view of an existing flip-chip integrated circuit package, in accordance with at least one embodiment of the present disclosure.

FIG. 3 is a schematic, diagrammatic, side cross-sectional view of the example flip-chip integrated circuit package of FIG. 2, in accordance with at least one embodiment of the present disclosure.

FIG. 4 is a schematic, diagrammatic, side cross-sectional view of an example substrate such as a printed circuit board (PCB) or laminate, in accordance with at least one embodiment of the present disclosure.

FIG. 5 is a schematic, diagrammatic, side-cross-sectional view of an example substrate to which a flip-chip integrated circuit has been bonded, in accordance with at least one embodiment of the present disclosure.

FIG. 6 is a schematic, diagrammatic, side-cross-sectional view of an example substrate to which a flip-chip integrated circuit has been bonded, in accordance with at least one embodiment of the present disclosure.

FIG. 7 is a schematic, diagrammatic, side-cross-sectional view of an example substrate to which a flip-chip integrated circuit has been bonded, in accordance with at least one embodiment of the present disclosure.

FIG. 8 is a schematic, diagrammatic, side-cross-sectional view of an example substrate to which a flip-chip integrated circuit has been bonded, in accordance with at least one embodiment of the present disclosure.

FIG. 9 is a schematic, diagrammatic, side-cross sectional view of an example flip-chip integrated circuit package, in accordance with at least one embodiment of the present disclosure.

FIG. 10 is a schematic, diagrammatic, side-cross sectional view of an example flip-chip integrated circuit package, in accordance with at least one embodiment of the present disclosure.

FIG. 11 is a schematic, diagrammatic, side-cross-sectional view of an example substrate to which a flip-chip integrated circuit has been bonded, in accordance with at least one embodiment of the present disclosure.

FIG. 12 is a schematic, diagrammatic, side-cross-sectional view of an example substrate to which a flip-chip integrated circuit has been bonded, in accordance with at least one embodiment of the present disclosure.

FIG. 13 is a schematic, diagrammatic, side-cross-sectional view of an example substrate to which a flip-chip integrated circuit has been bonded, in accordance with at least one embodiment of the present disclosure.

FIG. 14 is a schematic, diagrammatic, side-cross sectional view of an example flip-chip integrated circuit package, in accordance with at least one embodiment of the present disclosure.

FIG. 15 is a schematic, diagrammatic, side-cross sectional view of an example flip-chip integrated circuit package, in accordance with at least one embodiment of the present disclosure.

FIG. 16 is a schematic, diagrammatic view of an electronic device or a wireless device comprising a flip-chip integrated circuit package, in accordance with at least one embodiment of the present disclosure.

FIG. 17 is a schematic, diagrammatic representation, in flow diagram form, of an example gold-to-epoxy compatibility method, in accordance with at least one embodiment of the present disclosure.

### DETAILED DESCRIPTION

To address delamination and moisture intrusion challenges in RF IC flip chip packaging designs, there is a need for systems to enhance the adhesion between the die’s backside Au metallization and the epoxy mold compound. Such improvements help mitigate delamination risks and enhance the overall reliability of RF IC electronic packages in demanding environments where delamination and moisture intrusion are risks.

In accordance with at least one embodiment of the present disclosure, a gold-to-epoxy compatibility system is provided which enhances the adhesion between the epoxy molding compound and the Au metallization. Two options are disclosed.

Option 1: Adhesive print and cure on die backside prior to molding.

This innovation introduces a buffer layer on the die backside to enhance adhesion compatibility between the epoxy mold compound and the die’s backside Au metallization, thereby enhancing the reliability of the package. The buffer layer consists of an Au-compatible adhesive applied to the die’s backside and cured. This adhesive, typically a low-modulus epoxy, provides strong adhesion to both the Au surface and the mold compound. The package can then undergo transfer or compression molding using standard manufacturing processes, with curing performed at relatively low temperatures, typically around 100–150°C. This additional adhesive layer dramatically reduces the risk of delamination between the die backside Au and the mold compound during stress tests and field applications.

The process begins with the fabrication of a GaN or GaAs MMIC semiconductor die with one or more backside vias or through-semiconductor vias. Gold (Au) is applied as the backside metallization, serving as the MMIC RF ground plane and providing a connection between the backside via and the ground.

The assembly process starts with attaching the flip-chip (FC) die to a laminate (e.g., a printed circuit board or PCB). This may for example involve solder flux printing, die placement, and reflow. The module then undergoes underfill dispensing and curing.

Next, an adhesive material is printed onto the die’s Au backside and cured at low temperatures, typically between 100–150°C. The bondline thickness of this adhesive layer may be maintained in a range of 20–100 µm, although other thicknesses may be used instead or in addition. This adhesive acts as a buffer layer between the mold compound and the die’s backside Au metallization. The epoxy used in this layer provides high adhesion strength to the Au surface, while its low modulus of elasticity helps minimize stresses on the die and Cu pillar (CuP) bumps. Commercially available epoxies, such as DELO BS3770, are suitable for this application. Following the adhesive application, the module undergoes compression molding and post-mold curing. This approach effectively mitigates delamination between the die’s backside Au metallization and the mold compound during stress testing and in field applications as the mold compound has strong adhesion with the epoxy.

Option 2: Alternatively, a copper (Cu) mesh fabric or Cu block or foil can be attached to the die’s backside using an adhesive or a high-thermal-conductivity sintering material such as silver-filled epoxy. This process may for example involve dispensing the adhesive or sintering material, placing the Cu mesh or block, and curing the assembly. The Cu mesh or block not only improves adhesion with the mold compound but also aids in heat dissipation. An additional advantage of the Cu mesh is that submicron or nano-scale sintering particles can protrude onto the mesh’s surface, further enhancing its adhesion with the mold compound. This is followed by compression molding. The epoxy molding compound provides excellent adhesion strength with the Cu surface, while the sintering material ensures strong bonding with both Au and Cu surfaces. This approach enhances both mechanical and thermal performance, contributing to improved reliability of the package.

Both options effectively addresses the delamination issue in backside Au metallization encapsulated in plastic packages, ensuring greater reliability during stress tests and in field applications.

The present disclosure aids substantially in flip-chip packaging, by improving adhesion between the flip-chip backside gold metallization and the molding compound used to form the package. Implemented as one or more intermediate layers between the gold and the molding compound, the gold-to-epoxy compatibility system disclosed herein provides practical improvements in the reliability of packaged ICs. This augmented adhesion transforms an IC package that is subject to delamination into one where delamination is unlikely, without the normally routine need to use a non-Au ground plane on the backside of the flip chip. This unconventional approach improves the functioning of the IC package, by reducing the risk of moisture intrusion.

These descriptions are provided for exemplary purposes only, and should not be considered to limit the scope of the gold-to-epoxy compatibility system. Certain features may be added, removed, or modified without departing from the spirit of the claimed subject matter.

For the purposes of promoting an understanding of the principles of the present disclosure, reference will now be made to the embodiments illustrated in the drawings, and specific language will be used to describe the same. It is nevertheless understood that no limitation to the scope of the disclosure is intended. Any alterations and further modifications to the described devices, systems, and methods, and any further application of the principles of the present disclosure are fully contemplated and included within the present disclosure as would normally occur to one skilled in the art to which the disclosure relates. In particular, it is fully contemplated that the features, components, and/or steps described with respect to one embodiment may be combined with the features, components, and/or steps described with respect to other embodiments of the present disclosure. For the sake of brevity, however, the numerous iterations of these combinations will not be described separately.

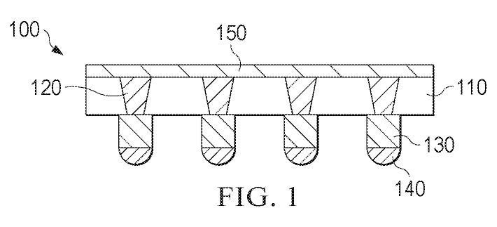

FIG. 1 is schematic, diagrammatic, side cross-sectional view of an existing flip-chip integrated circuit 100, in accordance with at least one embodiment of the present disclosure. The flip-chip integrated circuit includes a die 110 penetrated by metallized vias 120 that connect to pillars 130 (e.g., copper pillars, although other electrically conductive materials may be used instead or in addition) that terminate in solder caps 140. The vias 120 connect at least some pillars 130 to a backside gold layer 150.

Before continuing, it should be noted that the examples described above are provided for purposes of illustration, and are not intended to be limiting. Other devices and/or device configurations may be utilized to carry out the operations described herein.

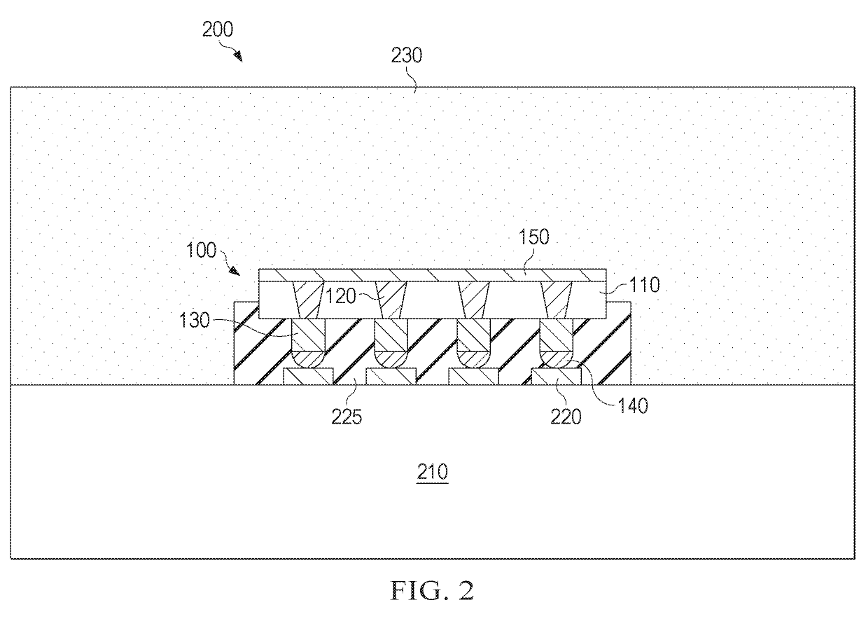

FIG. 2 is a schematic, diagrammatic, side cross-sectional view of an existing flip-chip integrated circuit package 200, in accordance with at least one embodiment of the present disclosure. Visible are the die 110, vias 120, pillars 130, solder caps 140, and backside gold layer 150 of the FC IC. The FC IC package also includes a substrate 210 with solder pads 220, an underfill compound 225, and a compression-molded molding compound 230.

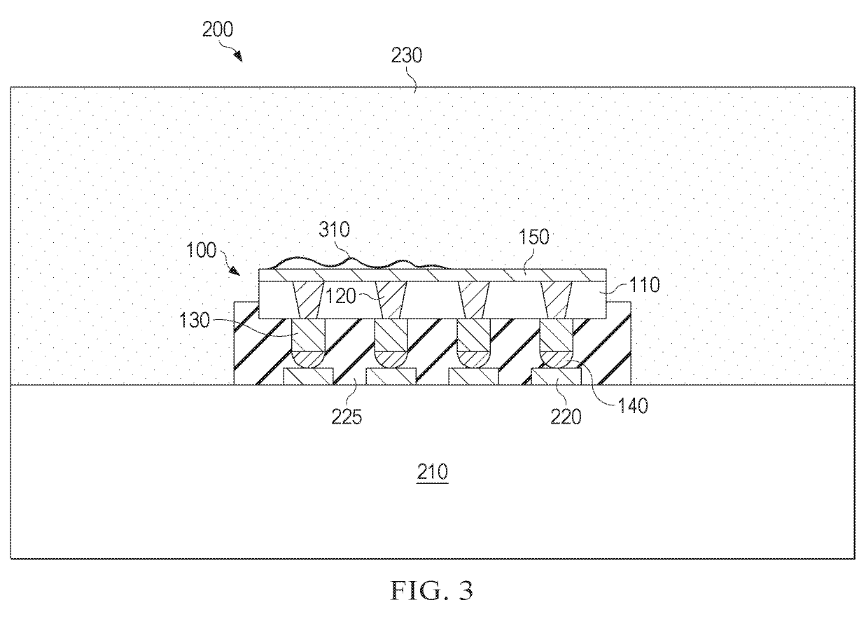

FIG. 3 is a schematic, diagrammatic, side cross-sectional view of the example flip-chip integrated circuit package 200 of FIG. 2, in accordance with at least one embodiment of the present disclosure. However, in the example shown in FIG. 3, a delamination 310 has occurred between the gold backside layer 150 and the molding compound 230, as a result of stress testing or field conditions such as shock, vibration, and thermal cycling. For example, During moisture-sensitive level 3 (MSL3) testing and subsequent reflow conditions, the mold compound can absorb moisture. As the temperature rises, this moisture expands, generating vapor pressure at the interface between the mold compound and the die’s backside. If the adhesion between the mold compound and the backside Au is insufficient, this pressure can lead to delamination, compromising the package’s reliability. Other possible drivers of delamination include, but are not limited to, mechanical shock, thermal shock, thermal cycling, vibration, bending modes, and rough handling.

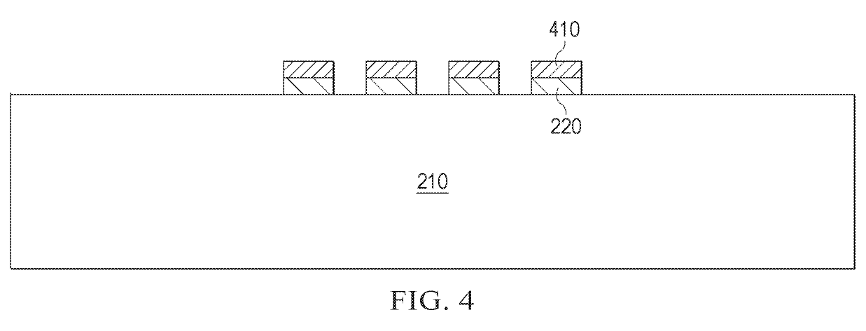

FIGS. 4-10 show a possible process for fabricating a FC IC package incorporating the gold-to-epoxy compatibility system according to Option 1.

FIG. 4 is a schematic, diagrammatic, side cross-sectional view of an example substrate 210 such as a printed circuit board (PCB) or laminate, in accordance with at least one embodiment of the present disclosure. The PCB or laminate may for example be made of FR4, to which epoxy molding compounds such as Sumitomo G311 Type C mold compound have excellent adhesion. The substrate 210 also includes solder pads 220 that may for example be made of gold or another conductive material. It is understood that the solder pads 220 may connect to traces (not shown) that electrically couple the solder pads 220 to other solder pads elsewhere on the substrate 210. Prior to bonding of the FC IC, a solder flux 410 may be printed onto the pads 220.

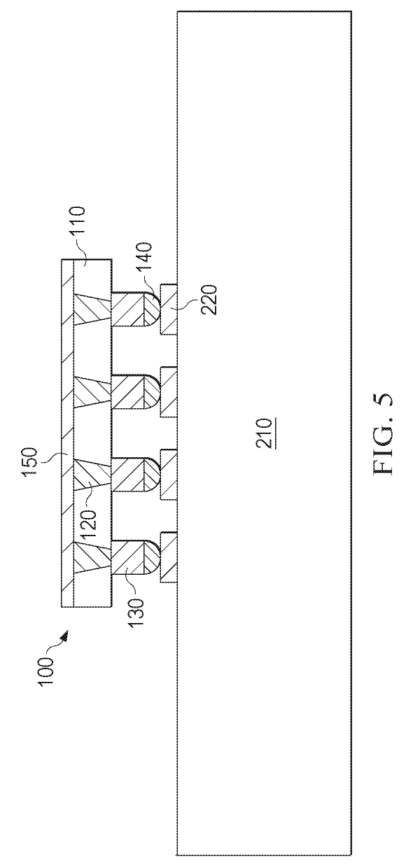

FIG. 5 is a schematic, diagrammatic, side-cross-sectional view of an example substrate 210 to which a flip-chip integrated circuit 100 has been bonded, in accordance with at least one embodiment of the present disclosure. Visible are the substrate 210, pads 220, and solder 140, as well as the die 110, vias 120, poses 130, and backside gold layer 150 of the FC IC 100. In a first production step, using a typical bonding process, the FC IC is positioned (e.g., by a pick-and-place machine) such that the posts 130 are aligned with the pads 220, and the substrate is then placed in a reflow oven at a temperature of 240-260°C to temporarily melt the solder 140, which then cools, forming an electrical, mechanical, and thermal bond between the pins 130 and their corresponding pads 220.

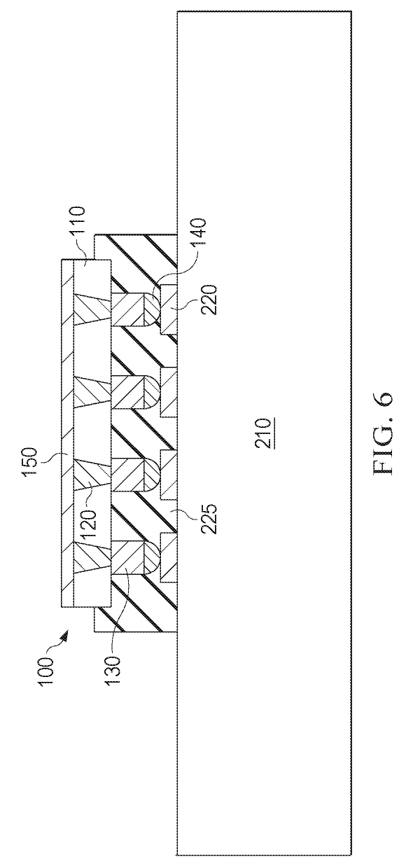

FIG. 6 is a schematic, diagrammatic, side-cross-sectional view of an example substrate 210 to which a flip-chip integrated circuit 100 has been bonded, in accordance with at least one embodiment of the present disclosure. Visible are the substrate 210, pads 220, and solder 140, as well as the die 110, vias 120, poses 130, and backside gold layer 150 of the FC IC 100. In a second production step, an underfill material 225, such as NAMICS U8410-73CF3 or Loctite 4531 is injected (e.g., by needle dispense or jet dispense) between the die 110 and the substrate 210. In an example, the underfill material 225 has been selected for good adhesion to both the die (e.g., GaN, GaAs) and the substrate (e.g., fiber-reinforced FR4), as well as for low coefficient of thermal expansion and low modulus of elasticity. After injection, the underfill material 225 is then cured (e.g., in a curing oven) at a temperature of around 150-160°C, which is sufficient to cure the underfill material 225 without reflowing the solder 140. The underfill material creates a strong mechanical bond between the die 110 and the substrate 210.

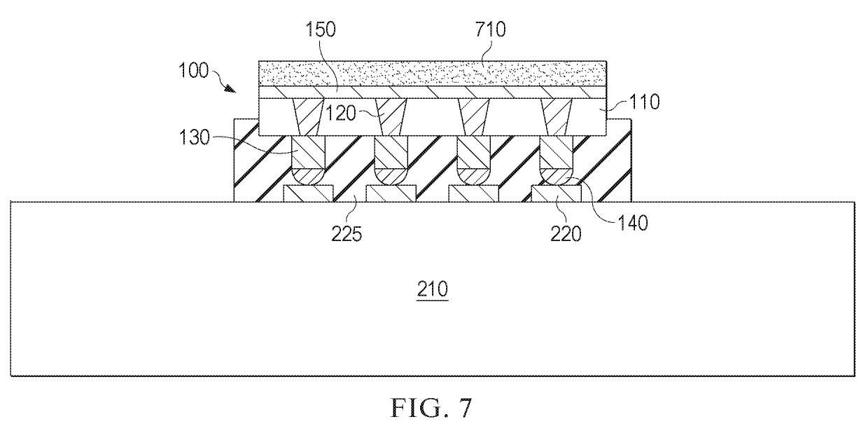

FIG. 7 is a schematic, diagrammatic, side-cross-sectional view of an example substrate 210 to which a flip-chip integrated circuit 100 has been bonded, in accordance with at least one embodiment of the present disclosure. Visible are the substrate 210, pads 220, and solder 140, as well as the die 110, vias 120, poses 130, and backside gold layer 150 of the FC IC 100, and the underfill material 225. In a third production step, an adhesive interlayer 710 (e.g., an epoxy such as DELO BS3770) is printed over the gold layer 150 and cured at a temperature of 100-140°C. In an example, the adhesive 710 is selected for good adhesion both to the gold layer 150 and to mold materials such as Sumitomo G311 Type C, as well as having a low modulus of elasticity, which helps minimize stresses on the die 110, pillars 130, and solder 140.

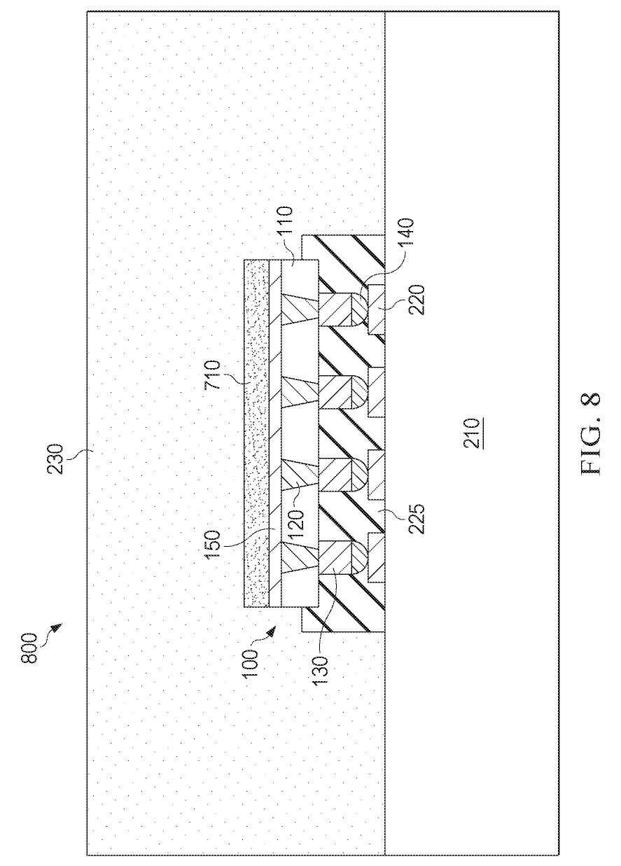

FIG. 8 is a schematic, diagrammatic, side-cross-sectional view of an example substrate 210 to which a flip-chip integrated circuit 100 has been bonded, in accordance with at least one embodiment of the present disclosure. Visible are the substrate 210, pads 220, and solder 140, as well as the die 110, vias 120, poses 130, and backside gold layer 150 of the FC IC 100, the underfill material 225, and the adhesive interlayer 710. In a fourth production step, the molding compound 230 is compression molded over the FC IC 100, completely enclosing it. The molding compound 230 is then cured at a temperature of 170-175°C. The molding compound forms a strong bond with the adhesive interlayer 710, die 110, underfill material 225, and substrate 210. The substrate 210, FC IC 100, and molding compound 230 now collectively form an FC IC package 800, incorporating the gold-to-epoxy compatibility system.

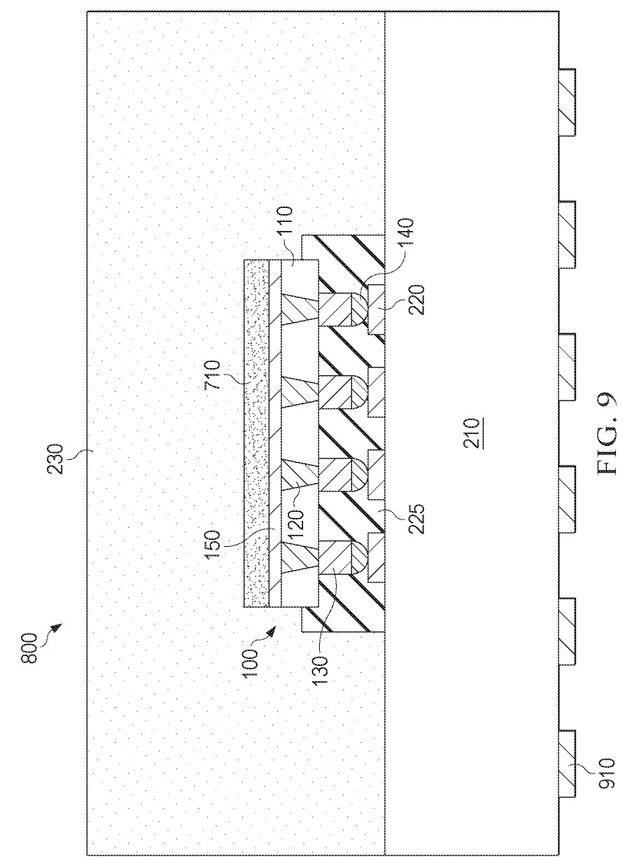

FIG. 9 is a schematic, diagrammatic, side-cross sectional view of an example flip-chip integrated circuit package 800, in accordance with at least one embodiment of the present disclosure. Visible are the substrate 210, pads 220, and solder 140, as well as the die 110, vias 120, poses 130, and backside gold layer 150 of the FC IC 100, the underfill material 225, the adhesive interlayer 710, and the molding compound 230. In a fifth production step, lands 910 may created on the bottom surface of the substrate 210, to form a land grid array (LGA). It is understood that traces, vias, and/or redistribution layers (not shown) in the substrate 210 may connect one or more lands 910 of the substrate with one or more pads 220 of the substrate.

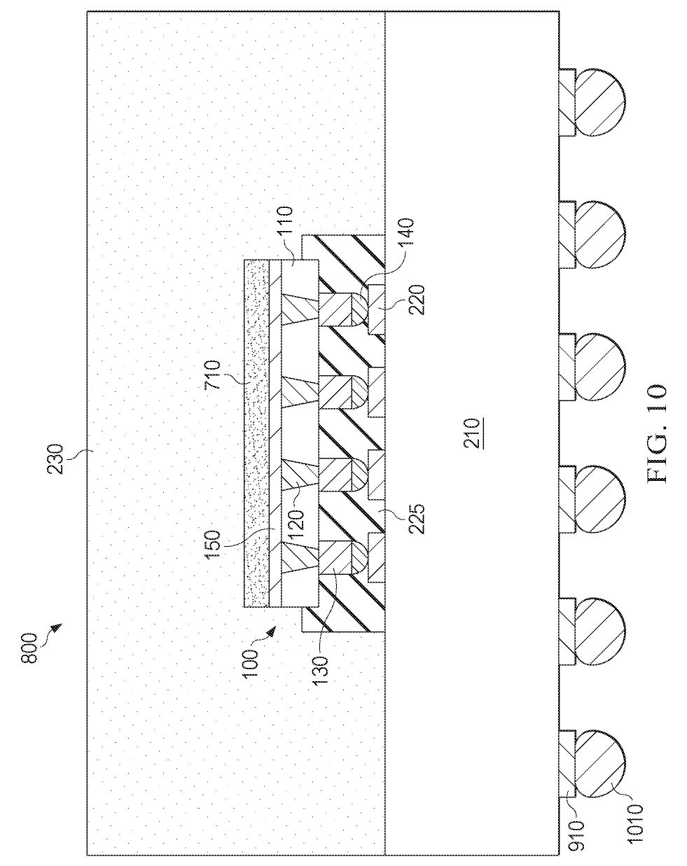

FIG. 10 is a schematic, diagrammatic, side-cross sectional view of an example flip-chip integrated circuit package 800, in accordance with at least one embodiment of the present disclosure. Visible are the substrate 210, pads 220, and solder 140, as well as the die 110, vias 120, poses 130, and backside gold layer 150 of the FC IC 100, the underfill material 225, the adhesive interlayer 710, the molding compound 230, and the lands 910. In an optional fifth production step, solder balls 1010 may added on the bottom surface of the lands 910, to form a ball grid array (BGA).

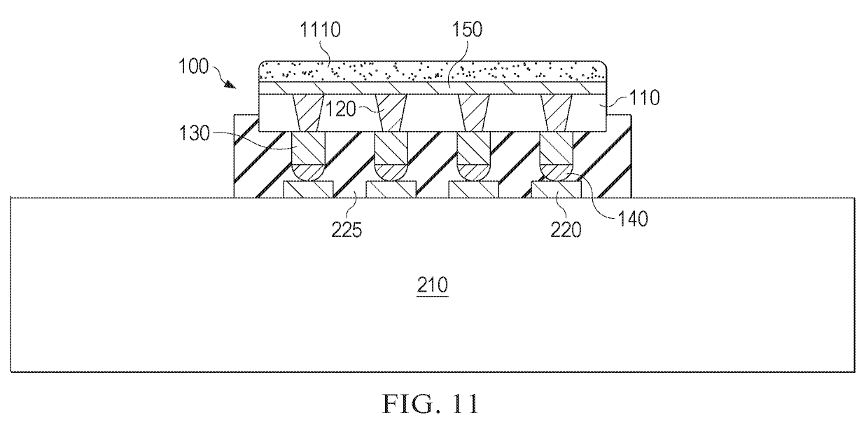

FIGS. 11-15 show a possible process for fabricating a FC IC package incorporating the gold-to-epoxy compatibility system according to Option 2.

FIG. 11 is a schematic, diagrammatic, side-cross-sectional view of an example substrate 210 to which a flip-chip integrated circuit 100 has been bonded, in accordance with at least one embodiment of the present disclosure. Visible are the substrate 210, pads 220, and solder 140, as well as the die 110, vias 120, poses 130, and backside gold layer 150 of the FC IC 100, and the underfill material 225. In an alternative third production step, an adhesive (e.g., Atrox 800HT5, Namics H9890-6A) or high-thermal-conductivity sinterable material (e.g., a silver nano-ink or silver-filled epoxy) 1110 is dispensed over the gold layer 150.

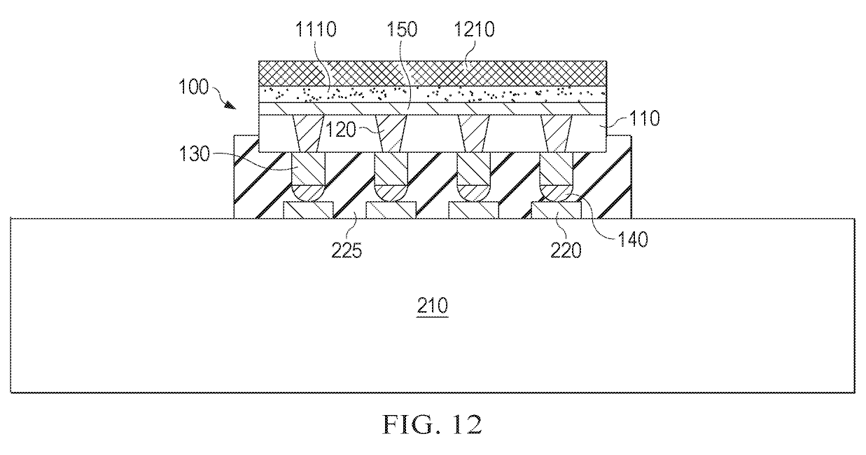

FIG. 12 is a schematic, diagrammatic, side-cross-sectional view of an example substrate 210 to which a flip-chip integrated circuit 100 has been bonded, in accordance with at least one embodiment of the present disclosure. Visible are the substrate 210, pads 220, and solder 140, as well as the die 110, vias 120, poses 130, and backside gold layer 150 of the FC IC 100, the underfill material 225, and the adhesive or high-thermal-conductivity sinterable material 1110. In an alternative fourth production step, a copper block, foil, or mesh 1210 is placed (e.g., with a pick-and-place machine) over the adhesive or high-thermal-conductivity sinterable material 1110. Copper may adhere much better than gold to the molding compound, and can also act as a heat spreader, thus improving the reliability of the FC IC 100. Furthermore, a mesh may be more desirable than a block or foil in that the mesh permits protrusion of the adhesive or high-thermal-conductivity sinterable material 1110 such that it can be in direct contact with the molding material, thus further enhancing adhesion.

Once the copper block, foil, or mesh 1210 has been placed, the adhesive 1110 may be cured and/or the sinterable material 1110 may be sintered (e.g., heated to a temperature of 200-220°C to coalesce the sinterable particles together), thus fully adhering the copper block, foil, or mesh 1210 to the gold layer 150.

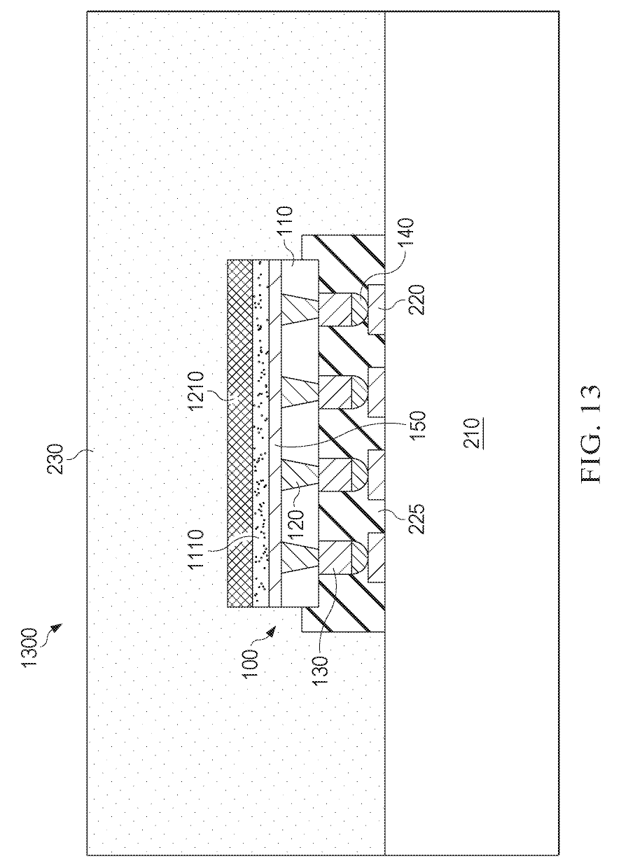

FIG. 13 is a schematic, diagrammatic, side-cross-sectional view of an example substrate 210 to which a flip-chip integrated circuit 100 has been bonded, in accordance with at least one embodiment of the present disclosure. Visible are the substrate 210, pads 220, and solder 140, as well as the die 110, vias 120, poses 130, and backside gold layer 150 of the FC IC 100, the underfill material 225, the cured adhesive or sintered layer 1110, and the copper mesh, foil, or block 1210. In an alternative fifth production step, the molding compound 230 is compression molded over the FC IC 100, completely enclosing it. The molding compound 230 is then cured. The molding compound forms a strong bond with the copper 1210, the cured adhesive or sintered layer 1110, die 110, underfill material 225, and substrate 210. The substrate 210, FC IC 100, and molding compound 230 now collectively form an FC IC package 1300, incorporating the gold-to-epoxy compatibility system.

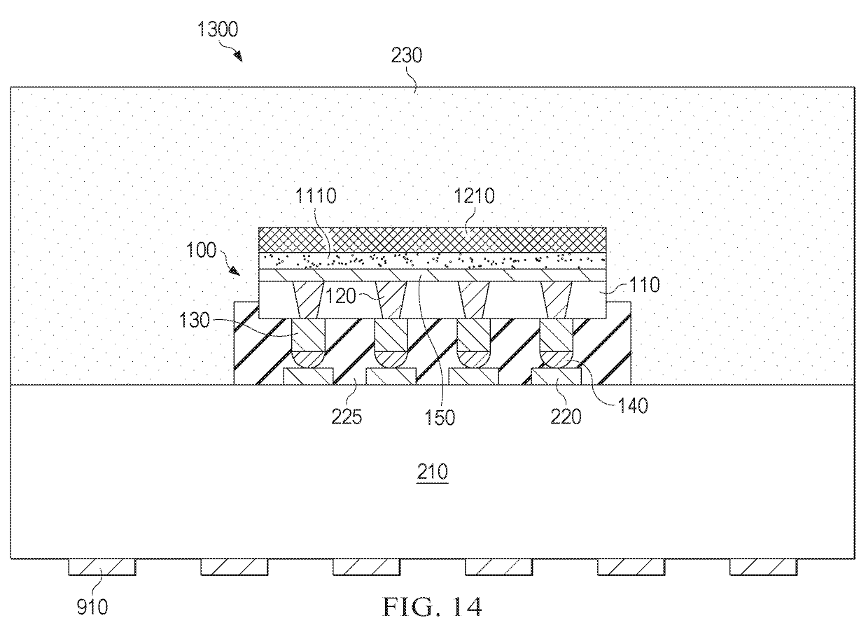

FIG. 14 is a schematic, diagrammatic, side-cross sectional view of an example flip-chip integrated circuit package 1300, in accordance with at least one embodiment of the present disclosure. Visible are the substrate 210, pads 220, and solder 140, as well as the die 110, vias 120, poses 130, and backside gold layer 150 of the FC IC 100, the underfill material 225, the cured adhesive or sintered layer 1110, the copper mesh, foil, or block 1210, and the molding compound 230. In an alternative sixth production step, lands 910 may created on the bottom surface of the substrate 210, to form a land grid array (LGA). It is understood that traces, vias, and/or redistribution layers (not shown) in the substrate 210 may connect one or more lands 910 of the substrate with one or more pads 220 of the substrate.

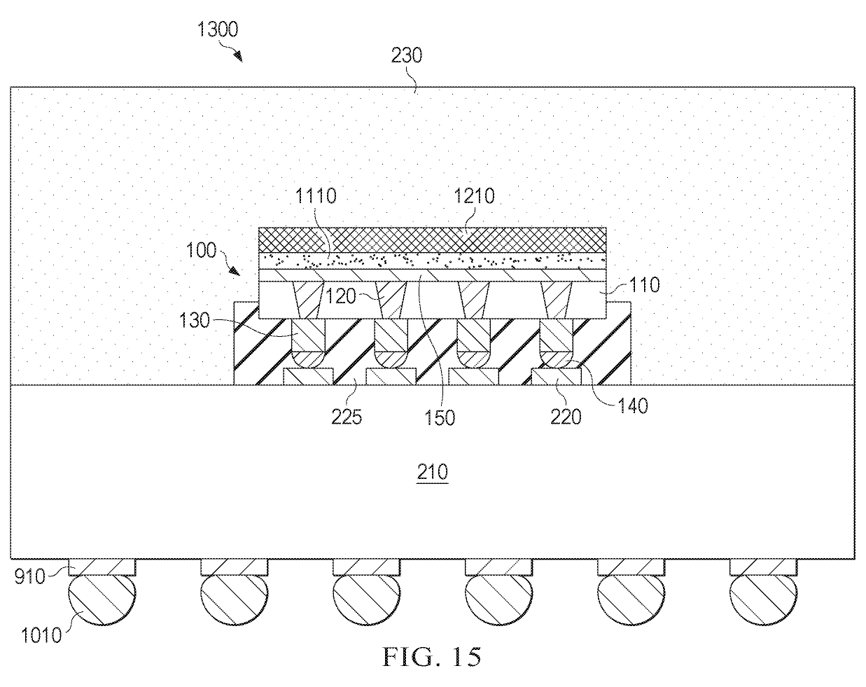

FIG. 15 is a schematic, diagrammatic, side-cross sectional view of an example flip-chip integrated circuit package 1300, in accordance with at least one embodiment of the present disclosure. Visible are the substrate 210, pads 220, and solder 140, as well as the die 110, vias 120, poses 130, and backside gold layer 150 of the FC IC 100, the underfill material 225, the adhesive interlayer 710, the molding compound 230, and the lands 910. In an optional seventh production step, solder balls 1010 may added on the bottom surface of the lands 910, to form a ball grid array (BGA).

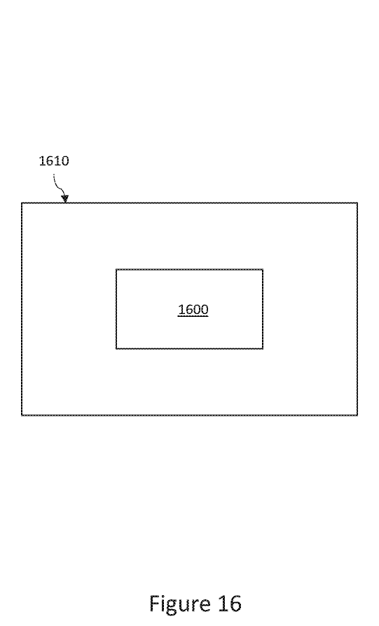

FIG. 16 is a schematic, diagrammatic view of an electronic device or a wireless device 1610 comprising a flip-chip integrated circuit package 1600, in accordance with at least one embodiment of the present disclosure. In some implementations, the electronic device or wireless device 1610 may include, for example, but not limited to, a computer, a cellular device, a satellite communication device, a wi-fi device, a radar, a global positioning system device, or any wireless device. In one or more embodiments, the FC IC package 1600 may include a FC IC die with a gold backing layer and at least one gold-to-epoxy compatibility layer, where the FC IC is mounted to a substrate and compression-molded to the substrate with a compression molding compound, such as FC IC package 800 of FIGS. 8-10, or FC IC package 1300 of FIGS. 13-16, or other FC IC package as described herein. The FC IC package 1600 may implement any RF component used in wireless applications, as an example, such as one or more RF power amplifiers or in a radar or radar systems; and the FC IC package 1600 may be coupled to other circuitry for implementing a wireless application.

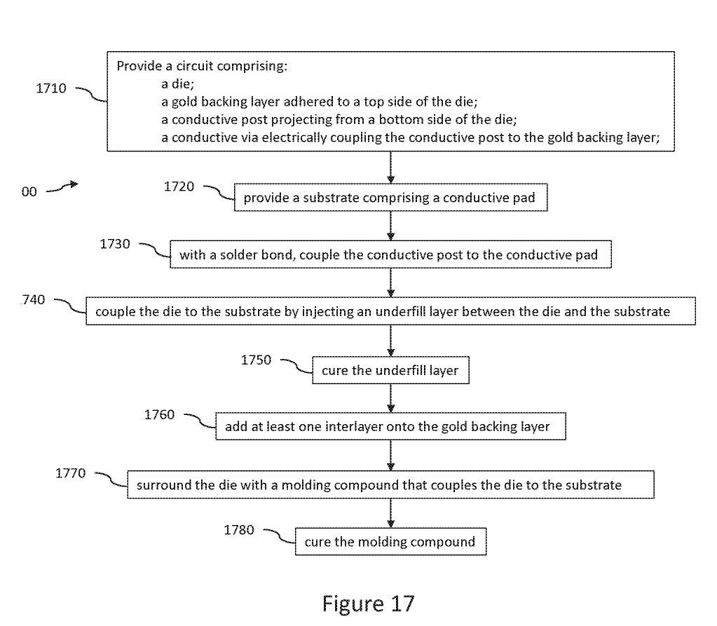

FIG. 17 is a schematic, diagrammatic representation, in flow diagram form, of an example gold-to-epoxy compatibility method 1700, in accordance with at least one embodiment of the present disclosure. Flow diagrams are provided herein for exemplary purposes; a person of ordinary skill in the art will recognize myriad variations that nonetheless fall within the scope of the present disclosure. It is understood that the steps of method 1700 may be performed in a different order than shown in FIG. 17, additional steps can be provided before, during, and after the steps, and/or some of the steps described can be replaced or eliminated in other embodiments.

In step 1710, the method 1700 includes providing a circuit that includes a die, a gold backing layer adhered to a top side of the die, a conductive post projecting from a bottom side of the die, and a conductive via electrically coupling the conductive post to the gold backing layer. Execution then proceeds to step 1720.

In step 1720, the method 1700 includes providing a substrate that includes a conductive pad. Execution then proceeds to step 1730.

In step 1730, the method 1700 includes, with a solder bond, coupling the conductive post to the conductive pad. Execution then proceeds to step 1740.

In step 1740, the method 1700 includes coupling the die to the substrate by injecting an underfill layer between the die and the substrate. Execution then proceeds to step 1750.

In step 1750, the method 1700 includes curing the underfill layer. Execution then proceeds to step 1760.

In step 1760, the method 1700 includes adding at least one interlayer onto the gold backing layer. Execution then proceeds to step 1770.

In step 1770, the method 1700 includes surrounding the die with a molding compound that couples the die to the substrate. Execution then proceeds to step 1780.

In step 1780, the method 1700 includes curing the molding compound.

As will be readily appreciated by those having ordinary skill in the art after becoming familiar with the teachings herein, the gold-to-epoxy compatibility system advantageously improves adhesion and reduces the risk of delamination in plastic-encapsulated FC IC packages with gold-backed FC ICs. Accordingly, it can be seen that the gold-to-epoxy compatibility system fills a need in the art, by providing an interlayer or interlayers that adhere well to both the gold and the molding material encapsulant.

A number of variations are possible on the examples and embodiments described above. For example, the substrate, underfill material, adhesive layer, sinterable material layer, mesh, foil, or block, die, and/or mold compound could be made from different materials than those described herein, while performing the same or a similar function and thus adhering to the spirit of the present disclosure. All curable materials may be cured individually, in groups, or may be cured simultaneously in a single step. Sinterable compounds may be made from various metals with or without a non-metallic matrix.

The technology described herein may be applied to radio frequency ICs of various types, including MMICs and otherwise, and may also be applied to digital ICs, or any flip-chip integrated circuit or component with a gold backing layer.

The logical operations making up the embodiments of the technology described herein are referred to variously as operations, steps, objects, elements, components, or modules. Furthermore, it should be understood that these may occur, or be performed or arranged, in any order, unless explicitly claimed otherwise or a specific order is inherently necessitated by the claim language.

All directional references e.g., upper, lower, inner, outer, upward, downward, left, right, lateral, front, back, top, bottom, above, below, vertical, horizontal, clockwise, counterclockwise, proximal, and distal are only used for identification purposes to aid the reader’s understanding of the claimed subject matter, and do not create limitations, particularly as to the position, orientation, or use of the gold-to-epoxy compatibility system. Connection references, e.g., attached, coupled, connected, joined, or “in communication with” are to be construed broadly and may include intermediate members between a collection of elements and relative movement between elements unless otherwise indicated. As such, connection references do not necessarily imply that two elements are directly connected and in fixed relation to each other. The term “or” shall be interpreted to mean “and/or” rather than “exclusive or.” The word “comprising” does not exclude other elements or steps, and the indefinite article “a” or “an” does not exclude a plurality. Unless otherwise noted in the claims, stated values shall be interpreted as illustrative only and shall not be taken to be limiting.

The above specification, examples and data provide a complete description of the structure and use of exemplary embodiments of the gold-to-epoxy compatibility system as defined in the claims. Although various embodiments of the claimed subject matter have been described above with a certain degree of particularity, or with reference to one or more individual embodiments, those skilled in the art could make numerous alterations to the disclosed embodiments without departing from the spirit or scope of the claimed subject matter.

Still other embodiments are contemplated. It is intended that all matter contained in the above description and shown in the accompanying drawings shall be interpreted as illustrative only of particular embodiments and not limiting. Changes in detail or structure may be made without departing from the basic elements of the subject matter as defined in the following claims.

What is claimed is:

1. A circuit package, comprising:
a die;
a gold backing layer adhered to a top side of the die; a conductive post projecting from a bottom side of the die; a conductive via electrically coupling the conductive post to the gold backing layer; a substrate comprising a conductive pad;
a solder bond coupling the conductive post to the conductive pad; a cured underfill layer positioned between the die and the substrate and coupling the die to the substrate; a cured molding compound surrounding the die and coupling the die to the substrate; and at least one interlayer coupling the gold backing layer to the molding compound.

2. The circuit package of claim 1, wherein the at least one interlayer comprises a cured adhesive.

3. The circuit package of claim 2, wherein the cured adhesive comprises an epoxy.

4. The circuit package of claim 1, wherein the at least one interlayer comprises a sintered material.

5. The circuit package of claim 1, wherein the at least one interlayer comprises a conductive mesh, block, or foil.

6. The circuit package of claim 1, wherein the at least one interlayer has a composition selected to adhere to both the gold backing layer and the cured molding compound.

7. The circuit package of claim 1, further comprising a land grid array or ball grid array coupled to a bottom side of the substrate.

8. A method for producing a circuit package, comprising: providing a circuit comprising:
a die;
a gold backing layer adhered to a top side of the die; a conductive post projecting from a bottom side of the die; a conductive via electrically coupling the conductive post to the gold backing layer; providing a substrate comprising a conductive pad; with a solder bond, coupling the conductive post to the conductive pad; coupling the die to the substrate by injecting an underfill layer between the die and the substrate; curing the underfill layer;
adding at least one interlayer onto the gold backing layer; surrounding the die with a molding compound that couples the die to the substrate; and curing the molding compound.

9. The method of claim 8, wherein the at least one interlayer comprises an adhesive, and wherein the method further comprises curing the adhesive.

10. The method of claim 9, wherein the adhesive comprises an epoxy.

11. The method of claim 8, wherein the at least one interlayer comprises a sinterable material, and wherein the method further comprises sintering the sinterable material.

12. The method of claim 8, wherein the at least one interlayer comprises a conductive mesh, block, or foil.

13. The method of claim 8, wherein the at least one interlayer has a composition selected to adhere to both the gold backing layer and the cured molding compound.

14. The method of claim 8, further comprising coupling a land grid array or ball grid array to a bottom side of the substrate.

15. A wireless device, comprising:
a circuit package, comprising:
a die;
a gold backing layer adhered to a top side of the die; a conductive post projecting from a bottom side of the die; a conductive via electrically coupling the conductive post to the gold backing layer; a substrate comprising a conductive pad;
a solder bond coupling the conductive post to the conductive pad; a cured underfill layer positioned between the die and the substrate and coupling the die to the substrate; a cured molding compound surrounding the die and coupling the die to the substrate; and at least one interlayer coupling the gold backing layer to the molding compound.

16. The wireless device of claim 15, wherein the at least one interlayer comprises a cured adhesive.

17. The wireless device of claim 16, wherein the cured adhesive comprises an epoxy.

18. The wireless device of claim 15, wherein the at least one interlayer comprises a sintered material.

19. The wireless device of claim 15, wherein the at least one interlayer comprises a conductive mesh, block, or foil.

20. The wireless device of claim 15, further comprising a land grid array or ball grid array coupled to a bottom side of the substrate.
